(19) United States
(12) Patent Application Publication
(10) Pub. No.: US 2021/0313194 A1
(43) Pub. Date: Oct. 7, 2021

(54) METHOD FOR MANUFACTURING SEMICONDUCTOR DEVICE AND MANUFACTURING APPARATUS

(71) Applicant: KABUSHIKI KAISHA TOSHIBA, Tokyo (JP)

(72) Inventors: Takayuki TAJIMA, Sagamihara (JP); Kazuo SHIMOKAWA, Yokohama (JP)

(73) Assignee: KABUSHIKI KAISHA TOSHIBA, Tokyo (JP)

(21) Appl. No.: 17/192,964

(22) Filed: Mar. 5, 2021

(30) Foreign Application Priority Data
Apr. 1, 2020 (JP) 2020-065531

(51) Int. Cl. H01L 21/48; H01L 23/00; H01L 21/56; H01L 21/683

(52) U.S. Cl. CPC H01L 21/4846; H01L 24/81; H01L 21/6835; H01L 21/561; H01L 21/565; H01L 24/97

(57) ABSTRACT

A method for manufacturing a semiconductor device includes forming first and second interconnect layers on first and second substrates, respectively; adhering the first and second substrates so that the back surfaces thereof face each other; bonding first and second semiconductor chips on the first and second interconnect layers, respectively; forming first and second molded bodies on the first and second substrates, respectively, while the first and second substrates are adhered; and detaching the first and second molded bodies from the first and second substrates. The first molded body includes the first interconnect layer, the first semiconductor chip and a first resin layer covering the first semiconductor chip on the first interconnect layer. The second molded body includes the second interconnect layer, the second semiconductor chip and a second resin layer covering the second semiconductor chip on the second interconnect layer. The first and second resin layers are formed simultaneously.

### CROSS-REFERENCE TO RELATED APPLICATIONS

This application is based upon and claims the benefit of priority from Japanese Patent Application No. 2020-065531, filed on Apr. 1, 2020; the entire contents of which are incorporated herein by reference.

### FIELD

Embodiments described herein relate generally to a method for manufacturing a semiconductor device and a manufacturing apparatus.

### BACKGROUND

There is a semiconductor device in which a semiconductor chip is mounted on an interconnect layer, and the semiconductor device is downsized by resin-molding. Such a semiconductor device can be thinner and have less occupied area on a printed circuit board.

### BRIEF DESCRIPTION OF THE DRAWINGS

FIG. 1 is a schematic cross-sectional view showing a semiconductor device according to an embodiment;

FIGS. 2A to 4B are schematic cross-sectional views showing manufacturing processes of the semiconductor device according to the embodiment; and

FIGS. 5A to 6C are schematic cross-sectional views showing manufacturing processes using the manufacturing apparatus according to the embodiment.

### DETAILED DESCRIPTION

According to one embodiment, a semiconductor device includes a semiconductor chip, an interconnect layer including an interconnect connected to the semiconductor chip, and a resin layer sealing the semiconductor chip on the interconnect layer. A method for manufacturing the semiconductor device includes forming a first interconnect layer on a first substrate; forming a second interconnect layer on a second substrate; and adhering the first substrate and the second substrate. The first substrate includes a first front surface and includes a first back surface at a side opposite to the first front surface. The first interconnect layer is provided on the first front surface. The second substrate includes a second front surface and included a second back surface at a side opposite to the second front surface. The second interconnect layer is provided on the second front surface. The first and second substrates being adhered so that the first and second back surfaces face each other. The method further includes bonding a first semiconductor chip on the first interconnect layer; bonding a second semiconductor chip on the second interconnect layer; forming a first molded body on the first front surface of the first substrate adhered to the second substrate; forming a second molded body on the second front surface of the second substrate adhered to the first substrate; detaching the first molded body from the first substrate; and detaching the second molded body from the second substrate. The first molded body includes the first interconnect layer, the first semiconductor chip and a first resin layer. The first resin layer covers the first semiconductor chip on the first interconnect layer. The second molded body includes the second interconnect layer, the second semiconductor chip and a second resin layer. The resin layer covers the second semiconductor chip on the second interconnect layer. The first and second resin layers are formed simultaneously.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

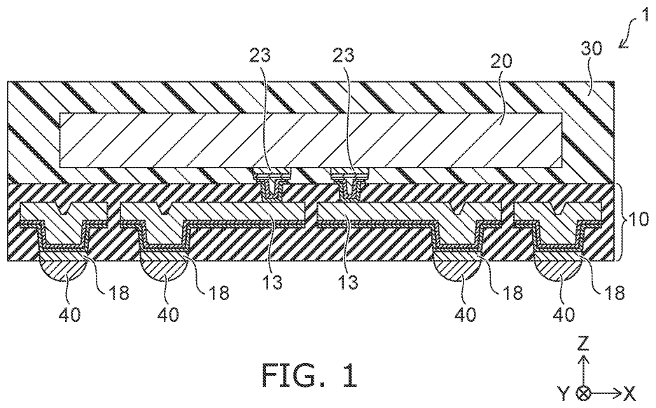

FIG. 1 is a schematic cross-sectional view showing a semiconductor device 1 according to an embodiment. The semiconductor device 1 has a structure in which a semiconductor chip is sealed in a so-called Fan Out Wafer Level Package (FOWLP).

As shown in FIG. 1, the semiconductor device 1 includes an interconnect layer 10, a semiconductor chip 20, a resin layer 30, and a solder bump 40. The interconnect layer 10 has a front surface and has a back surface opposite to the front surface. The semiconductor chip 20 is mounted on the front surface of the interconnect layer 10 and is sealed on the interconnect layer 10 with the resin layer 30. The solder bump 40 is provided on the back surface of the interconnect layer 10. The solder bump 40 is electrically connected to the semiconductor chip 20 via a connection terminal 18 and an interconnect 13 of the interconnect layer 10.

The semiconductor device 1 can be made thinner by reducing the thickness in a direction from the back surface toward the front surface (e.g. the Z-direction). The interconnect layer 10 includes the interconnect 13 that electrically connects the solder bump 40 and a bonding pad 23 of the semiconductor chip 20. The interconnect 13 is provided to be a short signal transfer path which improves the quality of the signals input to the semiconductor chip 20 and output from the semiconductor chip 20.

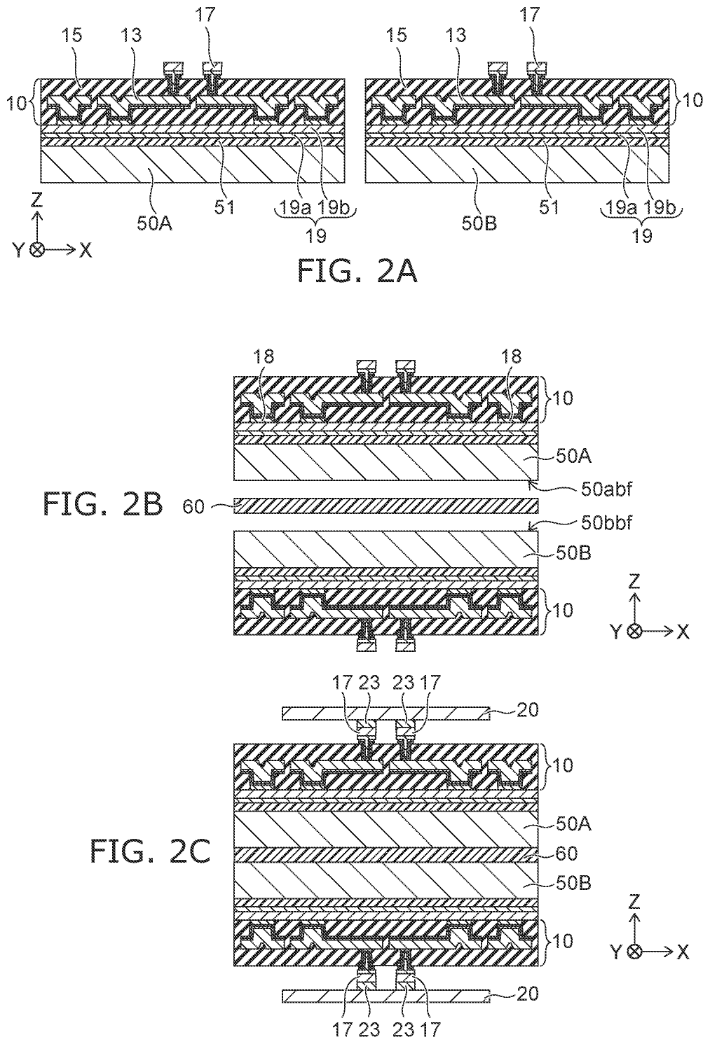

A method for manufacturing the semiconductor device 1 will now be described with reference to FIGS. 2A to 4B. FIGS. 2A to 4B are schematic cross-sectional views showing manufacturing processes of the semiconductor device 1 according to the embodiment.

As shown in FIG. 2A, the interconnect layers 10 are formed on the front surfaces of a substrate 50A and a substrate 50B, respectively, with a metal layer 19 interposed. The substrates 50A and 50B are, for example, silicon substrates or glass substrates.

The interconnect layer 10 includes the interconnect 13, a resin layer 15, a connection terminal 17, and the connection terminal 18. The interconnect 13 includes, for example, copper. The resin layer 15 covers and electrically insulates the interconnect 13. The resin layer 15 is, for example, an epoxy resin. The connection terminal 18 includes, for example, nickel.

The connection terminal 17 is exposed at the front surface side of the interconnect layer 10. The connection terminal 17 includes, for example, a connection member such as a solder material, etc., at the front end thereof. The connection terminal 17 includes, for example, nickel, copper, etc.

For example, the metal layer 19 has a stacked structure including a first layer 19a and a second layer 19b. The metal layer 19 is provided between the substrate 50A and the interconnect layer 10. Another metal layer 19 is provided between the substrate 50B and the interconnect layer 10. The first layer 19a includes, for example, copper. The second layer 19b is provided between the first layer 19a and the substrate 50A. The second layer 19b is also provided between the first layer 19a and the substrate 50B. The second layer 19b includes, for example, titanium.

The substrate 50A and the substrate 50B each are bonded to the metal layers 19 with a release layer 51 interposed. The release layer 51 is, for example, a sheet-like adhesive layer.

The substrate 50A and the substrate 50B are adhered to each other as shown in FIG. 2B. For example, a back surface 50abf of the substrate 50A and a back surface 50bbf of the substrate 50B are placed to face each other with a sheet-like adhesive layer 60 interposed, and are adhered to each other via the sheet-like adhesive layer 60. The adhesive layer 60 includes a material that has a weaker adhesive force than a adhesive force of the material of the release layer 51. Here, adhering means to be temporarily bondable and detachable.

As shown in FIG. 2C, the semiconductor chips 20 are bonded to the front surface sides of the interconnect layers 10 after adhering the substrate 50A and the substrate 50B. The semiconductor chips 20 are bonded respectively onto the interconnect layers 10 provided at the front surface side of the substrate 50A and the front surface side of the substrate 50B.

The semiconductor chip 20 is bonded so that the bonding pad 23 of the semiconductor chip 20 and the connection terminal 17 of the interconnect layer 10 are connected via the solder member. For example, the semiconductor chip 20 is flip-chip bonded on the interconnect layer 10.

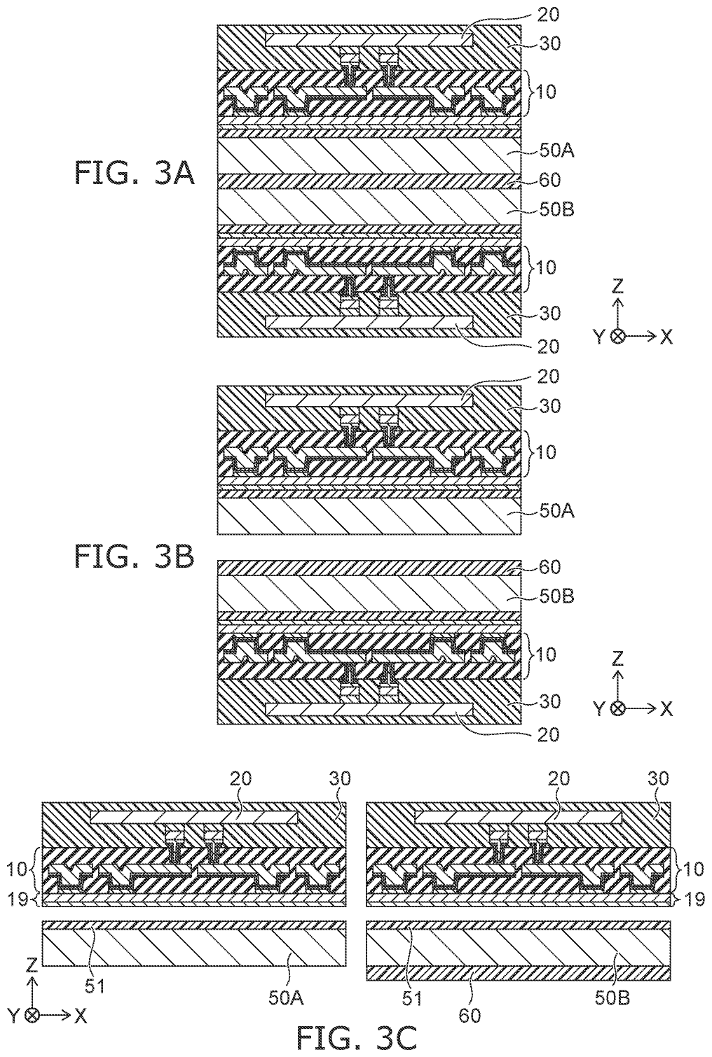

As shown in FIG. 3A, the semiconductor chip 20 is sealed by forming the resin layer 30 on the interconnect layer 10. The resin layer 30 is, for example, an epoxy resin. The resin layers 30 are simultaneously formed at both the front surface side of the substrate 50A and the front surface side of the substrate 50B, respectively.

As shown in FIG. 3B, the substrate 50A and the substrate 50B are separated at the interface between the substrate 50A and the adhesive layer 60. The substrate 50A and the substrate 50B may be separated at the interface between the substrate 50B and the adhesive layer 60.

As shown in FIG. 3C, the molded bodies each including the interconnect layer 10, the semiconductor chip 20, the resin layer 30 and the metal layer 19 are detached from the substrate 50A and the substrate 50B. For example, the interconnect layers 10 are detached from the substrate 50A and the substrate 50B at each interface between the metal layer 19 and the release layer 51.

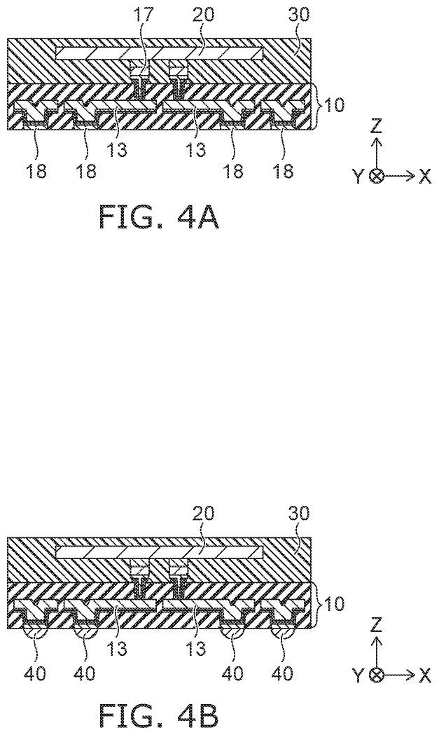

As shown in FIG. 4A, the connection terminal 18 is exposed by removing the metal layer 19 from the back surface of the molded body. For example, the metal layer 19 is removed by wet etching.

As shown in FIG. 4B, the solder bump 40 is formed on the connection terminal 18. For example, the solder bump 40 is formed through the solder reflow.

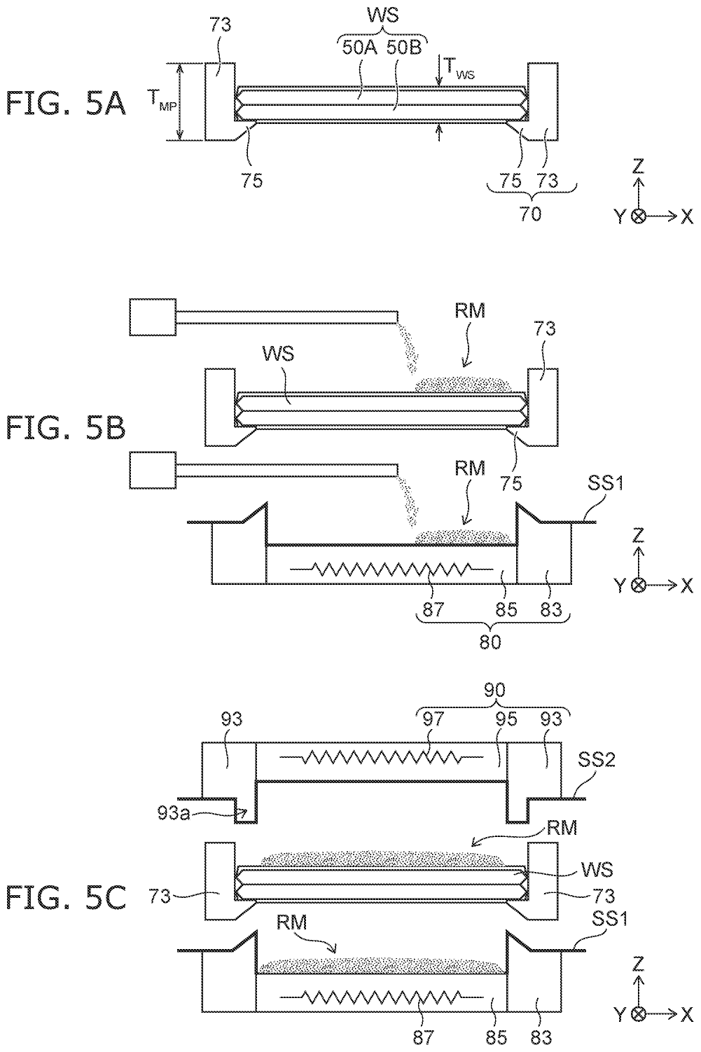

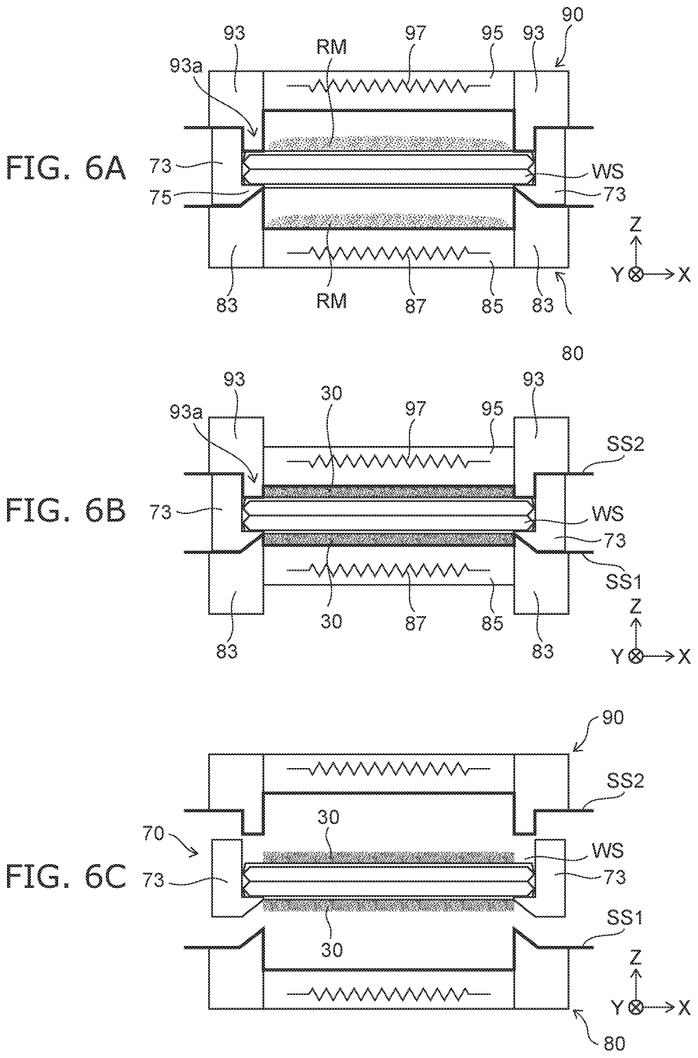

A method for forming the resin layer 30 will now be described with reference to FIGS. 5A to 6C. FIGS. 5A to 6C are schematic cross-sectional views showing manufacturing processes using the manufacturing apparatus according to the embodiment. The manufacturing apparatus is, for example, a molding die used for resin molding, and includes an intermediate jig 70, a lower die 80, and an upper die 90.

As shown in FIG. 5A, a composite substrate WS is placed on the intermediate jig 70. The composite substrate WS includes the substrate 50A and the substrate 50B. The interconnect layers 10 are provided on the front surface side of the substrate 50A and the front surface side of the substrate 50B; and the semiconductor chips 20 are bonded on the interconnect layers 10 (referring to FIG. 2C).

The intermediate jig 70 includes, for example, a frame body 73 and a wafer holding portion 75. The wafer holding portion 75 protrudes inward from the frame body 73. The composite substrate WS is placed on the wafer holding portion 75 in the space at the inner side of the frame body 73. The frame body 73 surrounds the composite substrate WS. A thickness T_{WS} in the Z-direction of the composite substrate WS is less than a thickness T_{MP} in the Z-direction of the frame body 73.

As shown in FIG. 5B, the lower die 80 is disposed below the intermediate jig 70. The lower die 80 includes, for example, a frame body 83, a movable presser 85, and a heater 87. The movable presser 85 is provided at the inner side of the frame body 83. The heater 87 is provided inside the movable presser 85.

The side surface of the movable presser 85 closely contacts the inner surface of the frame body 83. The movable presser 85 can move vertically with respect to the frame body 83. Also, the upper surface of the frame body 83 can engage the lower surface of the frame body 73 of the intermediate jig 70 and the lower surface of the wafer holding portion 75.

As shown in FIG. 5B, a resin member RM is supplied to the upper space that is surrounded with the frame body 73 and the composite substrate WS placed on the intermediate jig 70. The resin member RM also is supplied to the space surrounded with the frame body 83 and the movable presser 85 after disposing a release sheet SS1 that covers the inner surface of the frame body 83 of the lower die 80 and the front surface of the movable presser 85. The movable presser 85 is positioned at the lowermost level with respect to the frame body 83. The resin member RM is, for example, a granular thermosetting resin.

As shown in FIG. 5C, the upper die 90 is disposed above the intermediate jig 70. The upper die 90 includes, for example, a frame body 93, a movable presser 95, and a heater 97. The movable presser 95 is provided at the inner side of the frame body 93. The heater 97 is provided inside the movable presser 95. The movable presser 95 is positioned at the uppermost level with respect to the frame body 93. A release sheet SS2 is disposed to cover the inner surface of the frame body 93 and the lower surface of the movable presser 95.

The side surface of the movable presser 95 closely contacts the inner surface of the frame body 93. The movable presser 95 can move vertically with respect to the frame body 93. The lower surface of the frame body 93 can engage the upper surface of the frame body 73 of the intermediate jig 70. The frame body 93 also includes a protrusion 93a that protrudes downward and engages the inner surface of the frame body 73 of the intermediate jig 70.

As shown in FIG. 6A, the intermediate jig 70, the lower die 80, and the upper die 90 are caused to engage. The intermediate jig 70 is positioned between the lower die 80 and the upper die 90. The spaces that hold the resin members RM are provided between the lower die 80 and the composite substrate WS held by the intermediate jig 70 and between the composite substrate WS and the upper die 90.

The intermediate jig 70 and the lower die 80 engage in a state in which the lower surface of the frame body 73 closely contacts the upper surface of the frame body 83 via the release sheet SS1. The intermediate jig 70 and the upper die 90 are engaged in a state in which the upper surface of the frame body 73 closely contacts the lower surface of the frame body 93 via the release sheet SS2. The composite substrate WS is fixed between the wafer holding portion 75 and the protrusion 93a of the frame body 93. The spaces that hold the resin members RM are sealed between the lower die 80 and the composite substrate WS and between the upper die 90 and the composite substrate WS. For example, the spaces that hold the resin members RM may be depressurized.

As shown in FIG. 6B, the movable presser 85 is moved upward, the movable presser 95 is moved downward, and pressures are applied to the resin members RM. At this time, the resin members RM are heated by the heaters 87 and 97 provided in the movable pressers 85 and 95. When the resin member RM reaches the melting temperature, the resin member RM melts between the composite substrate WS and the movable presser 85 and fills the lower space between the composite substrate WS and the movable presser 85. The resin member RM also melts between the composite substrate WS and the movable presser 95 and fills the upper space between the composite substrate WS and the movable presser 95. The heating by the heaters 87 and 97 continues during the melting; and the resin layers 30 are formed by the resin members RM which are heated to a temperature equal to or greater than the curing temperature.

The resin layers 30 are preferably molded with the same thickness. For example, the spacing between the composite substrate WS and the movable presser 85 is substantially equal to the spacing between the composite substrate WS and the movable presser 95 when raising the movable presser 85 and lowering the movable presser 95. For example, the resin members RM are preferably supplied so that the amount of the resin member RM in the upper space is the same as the amount of the resin member RM in the lower space.

As shown in FIG. 6C, the lower die 80 and the upper die 90 are released from the intermediate jig 70. The resin layers are molded on the upper and lower surfaces of the composite substrate WS that is held by the intermediate jig 70. At this time, the resin layers 30 are in a half-cured state, for example.

After removing the composite substrate WS from the intermediate jig 70, the resin layer 30 is completely cured, for example, in an oven maintained at a temperature that is equal to or greater than the curing temperature of the resin member RM. Subsequently, the substrate 50A and the substrate 50B are separated as shown in FIG. 3B.

In the manufacturing method according to the embodiment, the resin layers 30 are simultaneously formed on the upper surface and the lower surface of the composite substrate WS in which the substrate 50A and the substrate 50B are bonded. The stresses due to the heat shrinkage and the curing shrinkage of the resin layer 30 are generated at both side of the composite substrate WS and can be canceled. Thereby, the stresses applied to the composite substrate WS can be reduced.

For example, when the resin layers 30 each are formed on the front surface sides of the substrates 50A and 50B without bonding the substrate 50A and the substrate 50B, stresses are applied to the substrates 50A and 50B due to the heat shrinkage and the curing shrinkage of the resin layer 30; and there may be cases where the interconnect layer 10 is detached from the substrate 50A or the substrate 50B at an unintended timing, and the molded body that includes the multiple semiconductor devices 1 may deform. There also may be cases where the substrate 50A or the substrate 50B is damaged. In contrast, according to the manufacturing method according to the embodiment, the manufacturing yield can be increased by reducing the stress generated in the process of forming the resin layer 30.

There is also a method in which, for example, the heat shrinkage and the curing shrinkage are reduced by mixing a filler such as silica, etc., into the resin member RM to suppress the stress of the resin layer 30 in the formation process thereof. However, when the filler content is high, the resin layer 30 may have the degraded airtightness, resulting in the lower reliability of the semiconductor device 1. According to the manufacturing method according to the embodiment, the stresses that are applied to the substrates 50A and 50B can be reduced even when the filler content of the resin layer 30 is small. Therefore, the resin layer 30 may have the improved airtightness, and the reliability of the semiconductor device 1 can be increased.

The manufacturing method according to the embodiment is not limited to the examples described above. For example, the interconnect layers 10 may be detached from the substrate 50A and the substrate 50B after molding the resin layers 30 at the surfaces to which the semiconductor chips 20 are bonded and before separating the substrate 50A and the substrate 50B. Also, the semiconductor chips 20 may be bonded on the interconnect layers 10 before adhering the substrate 50A and the substrate 50B.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A method for manufacturing a semiconductor device,
the semiconductor device including
a semiconductor chip,
an interconnect layer including an interconnect connected to the semiconductor chip, and
a resin layer sealing the semiconductor chip on the interconnect layer,
the method comprising:
forming a first interconnect layer on a first substrate;
forming a second interconnect layer on a second substrate;
adhering the first substrate and the second substrate, the first substrate including a first front surface and a first back surface, the first interconnect layer being provided on the first front surface, the first back surface being at a side opposite to the first front surface, the second substrate including a second front surface and a second back surface, the second interconnect layer being provided on the second front surface, the second back surface being at a side opposite to the second front surface, the first and second substrates being adhered so that the first and second back surfaces face each other;
bonding a first semiconductor chip on the first interconnect layer;
bonding a second semiconductor chip on the second interconnect layer;
forming a first molded body on the first front surface of the first substrate adhered to the second substrate, the first molded body including the first interconnect layer, the first semiconductor chip and a first resin layer, the first resin layer covering the first semiconductor chip on the first interconnect layer;
forming a second molded body on the second front surface of the second substrate adhered to the first substrate, the second molded body including the second interconnect layer, the second semiconductor chip and a second resin layer, the resin layer covering the second semiconductor chip on the second interconnect layer, the first and second resin layers being formed simultaneously;
detaching the first molded body from the first substrate; and
detaching the second molded body from the second substrate.

2. The method according to claim 1, wherein
after the first and second substrates are adhered, the first semiconductor chip is bonded on the first interconnect layer, and the second semiconductor chip is bonded on the second interconnect layer.

3. The method according to claim 1, wherein
the first interconnect layer is formed on the first substrate with a first release layer interposed, and
the second interconnect layer is formed on the second substrate with a second release layer interposed.

4. The method according to claim 3, wherein
the first substrate is adhered to the second substrate via an adhesive layer,
the first release layer and the second release layer each include a material having an adhesive force stronger than an adhesive force of the adhesive layer, and
the first molded body and the second molded body are detached respectively from the first and second substrates after the first and second substrates are separated.

5. The method according to claim 3, wherein
the first interconnect layer is formed on the first release layer with a first metal layer interposed, the first release layer being formed on the first substrate; and
the second interconnect layer is formed on the second release layer with a second metal layer interposed, the second release layer being formed on the second substrate.

6. The method according to claim 5, wherein
the first interconnect layer includes a first connection terminal and a first interconnect, the first connection terminal contacting the first metal layer, the first connection terminal including a different material from the first metal layer, the first interconnect electrically connecting the first semiconductor chip and the first connection terminal.

7. The method according to claim 6, wherein
the first connection terminal is exposed by removing the first metal layer after the first molded body is separated from the first substrate and the first release layer, and
a first bonding member is formed on the first connection terminal.

8. The method according to claim 7, wherein
the second interconnect layer includes a second connection terminal and a second interconnect, the second connection terminal contacting the second metal layer, the second connection terminal including a different material from the second metal layer, the second interconnect electrically connecting the second semiconductor chip and the second connection terminal.

9. The method according to claim 8, wherein
the second connection terminal is exposed by removing the second metal layer after the second molded body is separated from the second substrate and the second release layer, and
a second bonding member is formed on the second connection terminal.

10. The method according to claim 1, wherein
the first resin layer and the second resin layer each include a filler.

11. A manufacturing apparatus, comprising:
a lower die;
an upper die; and
an intermediate jig disposed between the lower die and the upper die,
the lower die including a first frame body and a first presser, the first presser being movable at an inner side of the first frame body, the first presser being movable in a direction from the lower die toward the upper die when the upper die is disposed on the lower die with the intermediate jig interposed,
the upper die including a second frame body and a second presser, the second presser being movable inside the second frame body, the second presser being movable in a direction from the upper die toward the lower die when the upper die is disposed on the lower die with the intermediate jig interposed,
the intermediate jig including a third frame body, and a molded-body-holding portion protruding inward from the third frame body,
the first frame body of the lower die including an upper surface engaging a lower surface of the third frame body,
the second frame body of the upper die including a lower surface engaging an upper surface of the third frame body.

12. The apparatus according to claim 11, wherein
the first pressor has a side surface closely contacting the first frame body; and the first frame body and the third frame body are configured to closely contact and engage each other so that a first space is sealed between the lower die and the intermediate jig.

13. The apparatus according to claim 11, wherein
the second presser has a side surface closely contacting the second frame body; and the second frame body and the third frame body are configured to closely contact and engage each other so that a second space is sealed between the upper die and the intermediate jig.

14. The apparatus according to claim 11, wherein
the second frame body of the upper die includes a protrusion engaging an inner surface of the third frame body of the intermediate jig, and
the protrusion of the second frame body and the molded-body-holding portion of the third frame body are configured to hold a molded body between the protrusion and the molded body holding portion when the upper die is disposed on the lower die with the intermediate jig interposed.

15. The apparatus according to claim 11, wherein
the lower die further includes a first heater provided inside the first presser, and
the upper die further includes a second heater provided inside the second presser.
